(19) United States
(12) Patent Application Publication
(10) Pub. No.: US 2025/0140712 A1
(43) Pub. Date: May 1, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Chih Hsin YANG, Hsinchu (TW); Hui-Zhong ZHUANG, Kaohsiung (TW); Mao-Nan WANG, Kaohsiung (TW)

(21) Appl. No.: 18/591,280

(22) Filed: Feb. 29, 2024

Related U.S. Application Data
(60) Provisional application No. 63/593,302, filed on Oct. 26, 2023.

(51) Int. Cl. H01L 23/00; H01L 21/768; H01L 23/48; H01L 25/065

(52) U.S. Cl. CPC H01L 23/562; H01L 21/76898; H01L 23/481; H01L 25/0657; H01L 2225/06544

(57) ABSTRACT

A semiconductor device structure and methods of forming the same are described. The structure includes a through silicon via (TSV) disposed in an interconnect structure and a substrate, a guard structure located in the interconnect structure surrounding the TSV, and an active region surrounding the guard structure. A space between the guard structure and the active region is free of dummy devices.

### CROSS-REFERENCE TO RELATED APPLICATIONS

This application claims priority to U.S. Provisional Application No. 63/593,302, filed on Oct. 26, 2023, the contents of which are hereby incorporated by reference in their entirety.

### BACKGROUND

A through silicon via (TSV) provides a pathway (e.g., for an electrical connection) between wafers stacked in a vertical direction in an electronic device. The TSV may facilitate an increased level of integration in packaging for electronic devices, such as three-dimensional integrated circuits (3DICs). A 3DIC may be formed by stacking two or more wafers, with one or more TSVs formed through at least one of the two or more wafers to provide a pathway to connect the two or more wafers to a substrate. TSVs may be formed in a wafer by forming a recess that extends partially through a substrate, and filling the recess with a conductive material, such as copper.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are views of a semiconductor device structure including a through silicon via (TSV), in accordance with some embodiments.

FIG. 1A-1 is a top view of the semiconductor device structure including the TSV, in accordance with alternative embodiments.

FIG. 1A-2 is a top view of the semiconductor device structure including the TSV, in accordance with alternative embodiments.

FIG. 2 is a cross-sectional side view of one of various stages of manufacturing the semiconductor device structure, in accordance with some embodiments.

FIG. 3A is an enlarged portion of the semiconductor device structure of FIG. 2, in accordance with some embodiments.

FIG. 3B is an enlarged portion of the semiconductor device structure of FIG. 2, in accordance with some embodiments.

FIG. 4 is a cross-sectional side view of one of various stages of manufacturing the semiconductor device structure, in accordance with some embodiments.

FIG. 5 is a cross-sectional side view of one of various stages of manufacturing the semiconductor device structure, in accordance with alternative embodiments.

FIG. 6A is an enlarged portion of the semiconductor device structure of FIG. 5, in accordance with some embodiments.

FIG. 6B is an enlarged portion of the semiconductor device structure of FIG. 5, in accordance with some embodiments.

FIG. 7 is a cross-sectional side view of one of various stages of manufacturing the semiconductor device structure, in accordance with alternative embodiments.

FIG. 8 is a top view of the semiconductor device structure, in accordance with some embodiments.

FIGS. 9A-9G illustrate enlarged portions of the semiconductor device structure of FIG. 8, in accordance with some embodiments.

FIGS. 10A and 10B are top views of the semiconductor device structure, in accordance with some embodiments.

FIGS. 11 and 12 illustrate IC design layouts including the semiconductor device structure, in accordance with some embodiments.

FIGS. 13A-13E illustrate semiconductor packages, in accordance with some embodiments.

FIG. 14 is a top view of the semiconductor device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, devices, such as semiconductor devices, in the vicinity of through silicon vias (TSVs) suffer serious performance degradation due to the stress induced by the TSVs. To minimize such performance variation, a keep-out-zone (KOZ) is imposed around a TSV where no other active devices can be placed within the KOZ. In some embodiments, to reduce non-uniform loading effects, dummy devices are disposed within the KOZ. For example, dummy devices may be placed between a guard structure and the active devices. The dummy devices in the KOZ improves the overall uniformity of distribution of devices, resulting in uniform loading effects. However, with the area occupied by the dummy devices, and TSVs are arranged outside of an active device region. In some applications, such as face-to-back (F2B) die-to-die (D2D) communications, in which TSV pitch determines the bandwidth of signaling. With the dummy devices occupying areas around the TSV, enablement of TSV pitch shrinkage becomes difficult. Embodiments of the present disclosure provide a TSV KOZ without dummy devices located between the guard structure and active devices and/or without dummy conductive features located between the guard structure and active conductive features. Instead, boundary cells or boundary tap cells of standard device are integrated into the TSV KOZ. Benefits such as high signal bandwidth (especially for SoIC F2B stacking), high power efficiency, lower area overhead (e.g., for both standard cell and SRAM periphery), better latch-up (e.g., more boundary tap cells), or better standard cell power, performance, area (PPA), may result from integrating TSV into standard cells.

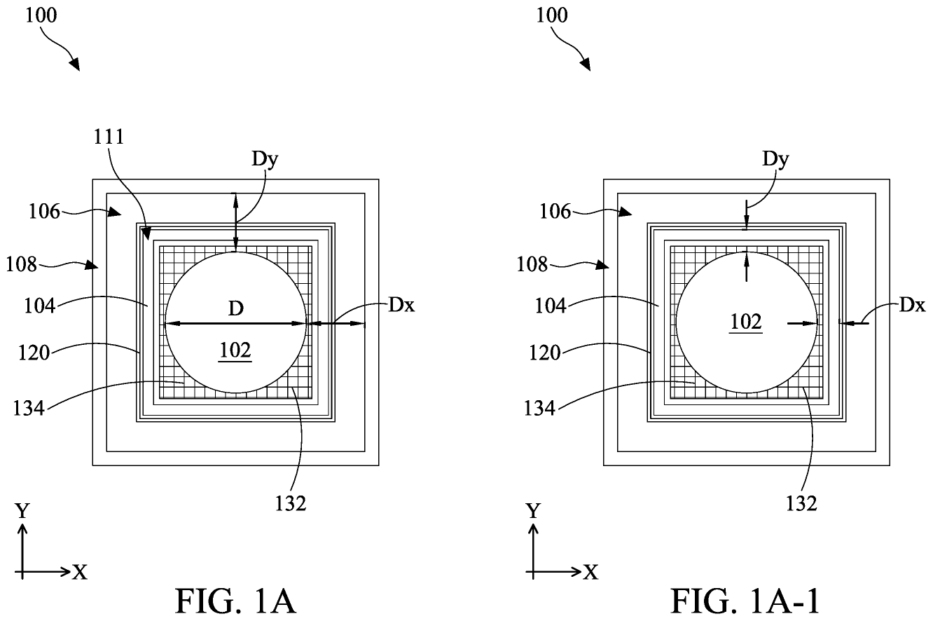

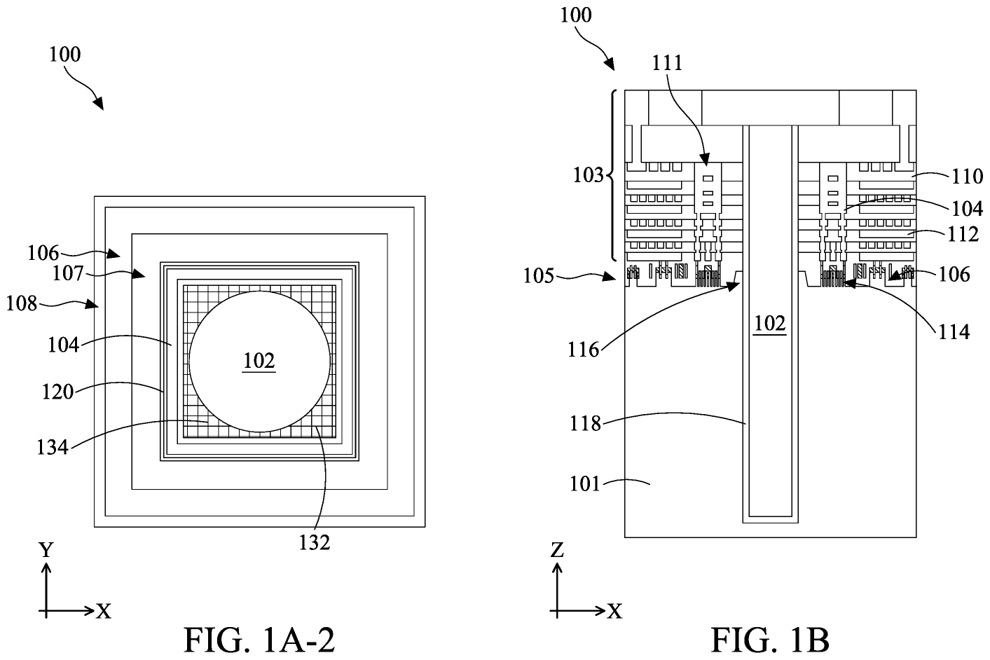

FIGS. 1A and 1B are views of a semiconductor device structure 100 including a TSV 102, in accordance with some embodiments. FIG. 1A is a top view of the semiconductor device structure 100, and FIG. 1B is a cross-sectional side view of the semiconductor device structure 100. As shown in FIGS. 1A and 1B, the semiconductor device structure 100 includes a substrate 101, such as a semiconductor wafer or a semiconductor die. The substrate 101 may be a semiconductor substrate, such as silicon, doped or undoped, or an active layer of a semiconductor-on-insulator (SOI) substrate. The substrate 101 may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Active and/or passive devices, such as transistors, diodes, capacitors, resistors, etc., may be formed in and/or on the substrate 101.

As shown in FIG. 1B, a plurality of devices 105 are formed on the substrate 101. The plurality of devices 105 may include any suitable devices, such as transistors, diodes, imaging sensors, resistors, capacitors, inductors, memory cells, or a combination thereof. In some embodiments, the plurality of devices 105 are transistors, such as planar field effect transistors (FETs), FinFETs, nanostructure transistors, forksheet FETs, complementary FETs (CFETs), or other suitable transistors. In some embodiments, the plurality of devices 105 include standard cells (STD), such as logic gates, such as an AND gate, an OR gate, an XOR gate, a NOT gate, a NAND gate, a NOR gate, and an XNOR gate, and combinational logic circuits such as a multiplexer, a flip-flop, an adder, and a counter. The STD of the plurality of devices 105 may be located in an active region 108, as shown in FIG. 1A. The plurality of devices 105 may further include boundary cells or tap cells located in a boundary region 106. Boundary cells may be cells placed at the boundary of the STD row to protect the STD from external signals. Tap cells may be cells for preventing latch-up, which is a type of short circuit that sometimes occur in integrated circuits. The boundary or tap cells are described in detail below. Because the plurality of devices 105 are active devices, the boundary region 106 is a part of the active region 108. In other words, the STD, tap cells, and boundary cells are all active devices.

As shown in FIG. 1B, an interconnect structure 103 is disposed over the substrate 101 and the plurality of devices 105. The interconnect structure 103 includes a plurality of dielectric layers 110, such as intermetal dielectric (IMD) layers. A plurality of conductive features 112 are formed in the dielectric layers 110 for providing signal and power to the plurality of devices 105. Thus, the conductive features 112 are active conductive features. The conductive features 112 may be conductive lines or conductive vias. The conductive features 112 may be made from one or more electrically conductive materials, such as metal, metal alloy, metal nitride, or silicide. For example, the conductive features 112 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof.

The semiconductor device structure 100 further includes a TSV 102 disposed in the interconnect structure 103 and the substrate 101. The TSV 102 includes an electrically conductive material, such as metal, for example copper. As shown in FIG. 1A, the TSV 102 may have a circular shape when viewed from the top. The TSV 102 may have any suitable shape, such as rectangular or square. In some embodiments, the TSV 102 has a dimension D ranging from about 0.1 microns to about 10 microns, such as from about 1 micron to about 5 microns. In some embodiments, a liner 118 is formed in an opening in the interconnect structure 103 and the substrate 101, and the TSV 102 is formed on the liner 118 in the opening. The liner 118 includes a dielectric material, such as an oxide or a nitride, and may be formed by a conformal process, such as atomic layer deposition (ALD). In some embodiments, a barrier layer (not shown) may be formed on the liner 118, and the TSV 102 is formed on the barrier layer. The barrier layer includes a metal or a metal nitride, such as Ti, TiN, Ta, TaN, or other suitable material.

In some embodiments, a buffer region 116 is formed on the substrate 101 between the plurality of devices 105 and the TSV 102. The buffer region 116 may protect the plurality of devices 105 during the formation of the TSV 102. In some embodiments, the buffer region is not present. For example, during the formation of an opening for the TSV 102, the buffer region is removed by the process to form the opening.

As described above, the semiconductor devices near a TSV may suffer performance degradation based on stress induced by the TSV and/or based on a process of forming the TSV. For example, water vapor and/or sulfur (e.g., produced during a cleaning operation in the process of forming the TSV) may damage a barrier layer of a semiconductor device near the TSV, which may allow metal of the TSV to diffuse into one or more dielectric layers that electrically insulate the semiconductor device. Diffusion of the metal into the one or more dielectric layers (e.g., low-k films) may cause the semiconductive device to have electrical shorts and/or may damage structural integrity of the semiconductor device.

To reduce performance degradation of semiconductor devices near a TSV, a guard structure 111 is formed around the TSV 102 to prevent water vapor and residual ions (e.g., produced during the process of forming the TSV 102) from penetrating dielectric layers and/or damaging barrier layers of the semiconductor devices, such as the plurality of devices 105 near the TSV 102. As shown in FIGS. 1A and 1B, in some embodiments, the guard structure 111 includes a guard ring 104 having a stack of conductive features disposed in the interconnect structure 103. In some embodiments, each conductive feature of the stack of conductive features is a closed-loop structure, unlike the conductive features 112, which are conductive lines or conductive vias. For example, the guard ring 104 is a continuous wall, as shown in FIG. 1A. The width of the closed-loop structures may vary, as shown in FIG. 1B. The material of the guard ring 104 may be the same as the material of the conductive features 112. In some embodiments, the guard ring 104 is formed simultaneously with the conductive features 112. In some embodiments, as shown in FIG. 1B, the guard structure 111 includes one guard ring 104. In some embodiments, the guard structure 111 includes multiple guard rings 104. For example, in some embodiments, the guard structure 111 includes a first guard ring surrounding the TSV and a second guard ring surrounding the first guard ring.

The guard ring 104 may further include dummy devices 114 formed on the substrate 101. The dummy devices 114 may be devices, such as transistors, not electrically connected to a signal source, a power source, or any active devices. In some embodiments, a dummy device is a transistor including a gate electrode, a source region, a drain region, and a channel region between the source region and the drain region. The dummy device 114 may be formed along with the active devices to improve loading effects. In some embodiments, the dummy devices 114 are not present, and the guard ring 104 includes a plurality of conductive features disposed in the interconnect structure 103.

As shown in FIG. 1A, in some embodiments, the KOZ may be defined by a dimension Dx along the X-direction and a dimension Dy along the Y-direction. The dimension Dx may extend from the TSV 102 to a location in an active region 108 along the X-direction, while the dimension Dy may extend from the TSV 102 to a location in the active region 108 along the Y-direction. The boundary region 106 is defined within the Dx and Dy, and boundary cells or tap cells of the active devices are placed in the boundary region 106. In some embodiments, the ratio of Dx to Dy is between about zero and about one. The boundary region 106 is a part of the active region 108, and the boundary region 106 is also a part of the KOZ. In such embodiments, the dimensions of the KOZ may be the same as the dimensions of the KOZ having dummy devices formed therein. In other words, in a circuit design, the design rule may include the KOZ having the dimensions Dx and Dy. However, the design rule is modified so that instead of placing dummy devices within the KOZ, boundary cells or tap cells of active devices are placed within the KOZ. In some embodiments, a ratio of the dimension Dx or Dy shown in FIG. 1A to the dimension D of the TSV 102 is greater than 1, such as from 1 to about 10.

FIG. 1A-1 is a top view of the semiconductor device structure 100 including the TSV 102, in accordance with alternative embodiments. In some embodiments, the dimensions of KOZ are changed in the design rule for designing a circuit. As shown in FIG. 1A-1, the KOZ is defined by the dimensions Dx and Dy, and the dimensions Dx, Dy extend from the TSV 102 to the guard ring 104, as shown in FIG. 1A-1. In some embodiments, the dimensions of the KOZ is substantially smaller than conventional KOZ, and no active devices are placed within the KOZ. In some embodiments, a ratio of the dimension Dx or Dy shown in FIG. 1A-1 to the dimension D of the TSV 102 is less than 1, such as from 0.1 to about 0.5.

In some embodiments, as shown in FIGS. 1A and 1A-1, a conductive feature 120 is formed to surround a portion of the guard ring 104. The conductive feature 120 may include the same material as a gate electrode layer of the active devices in the active region 108. The conductive feature 120 may be formed to protect the devices in the active region 108.

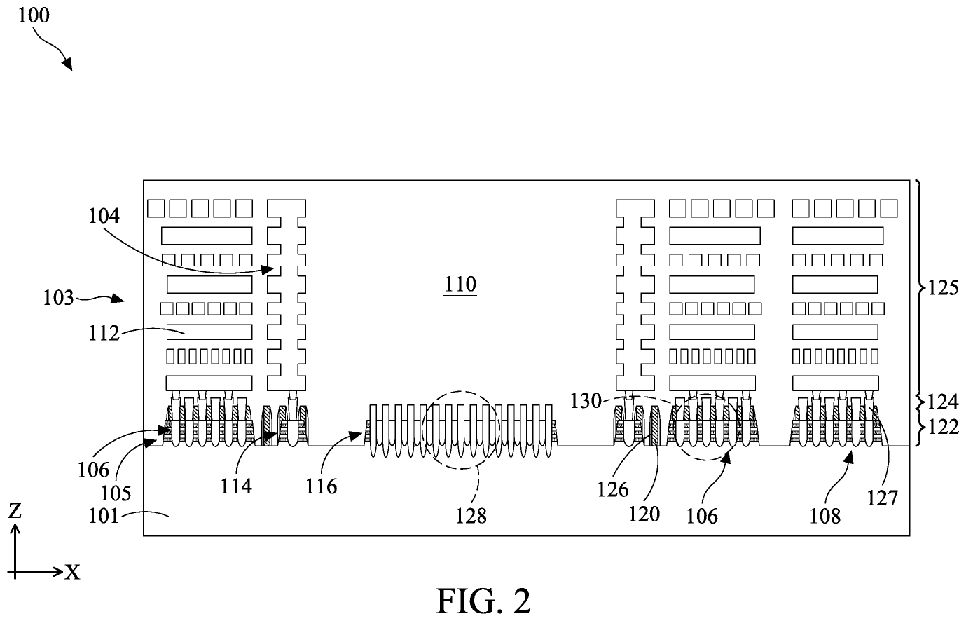

FIG. 1A-2 is a top view of the semiconductor device structure 100 including the TSV 102, in accordance with alternative embodiments. In some embodiments, a dummy region 107 is located around the guard ring 104, and the KOZ includes the dummy region 107. The dummy region 107 may include dummy devices located on the substrate 101 and/or a plurality of dummy conductive features located over the substrate 101 between the conductive features 112 (FIG. 1B) and the guard ring 104 (FIG. 1B) in the interconnect structure 103 (FIG. 1B). The boundary region 106 surrounds the dummy region 107, as shown in FIG. 1A-2. In some embodiments, two TSVs 102 cannot be placed within a die, because the space between the TSVs 102 for active devices is reduced due to the presence of the dummy region 107.

FIG. 2 is a cross-sectional side view of one of various stages of manufacturing the semiconductor device structure 100, in accordance with some embodiments. FIG. 2 illustrates the stage of manufacturing prior to forming an opening for the TSV 102. As shown in FIG. 2, front-end-of-line (FEOL) processes are performed to form devices in region 122, middle-of-line (MOL) processes are performed to form contacts in region 124, and back-end-of-line (BEOL) processes are performed to form the interconnect structure 103 in region 125. FEOL generally encompasses processes related to fabricating IC devices, such as transistors. For example, FEOL processes can include forming isolation features, gate structures, and source and drain regions (generally referred to as S/D regions). MOL generally encompasses processes related to fabricating contacts to conductive features (or conductive regions) of the IC devices, such as contacts to the gate structures and/or the S/D regions. BEOL generally encompasses processes related to fabricating the multilayer interconnect structure 103 that interconnects IC features fabricated by FEOL and MOL, thereby enabling operation of the IC devices.

As shown in FIG. 2, the plurality of devices 105 are located in the active region 108 and the boundary region 106. The dummy devices 114 of the guard ring 104, the conductive feature 120, and the buffer region 116 are also formed in the region 122 by the FEOL processes. In some embodiments, gate spacers 126 may be formed on opposite sidewalls of the conductive feature 120, as shown in FIG. 2. Conductive contacts 127 are formed in the region 124 by the MOL processes. The conductive contact 127 may include an electrically conductive material, such as TiN, W, Ru, Mo, Co, Cu, or other suitable electrically conductive material. The interconnect structure 103 is formed in the region 125 by the BEOL processes. The conductive features 112 and the stack of conductive features of the guard ring 104 are formed in the dielectric layers 110. Some conductive features 112 may be omitted for clarity. In some embodiments, the conductive features 112 electrically connect the plurality of devices 105 to external signal and/or power sources. In other words, the conductive features 112 may be formed in every dielectric layer 110 from the plurality of devices 105 to the top of the interconnect structure 103. In some embodiments, as shown in FIG. 2, the conductive features 112 are not formed in the dielectric layers 110 over the buffer region 116. Thus, the region where the opening for the TSV 102 would be formed is a metal-free space, which makes the opening for the TSV 102 easier to form.

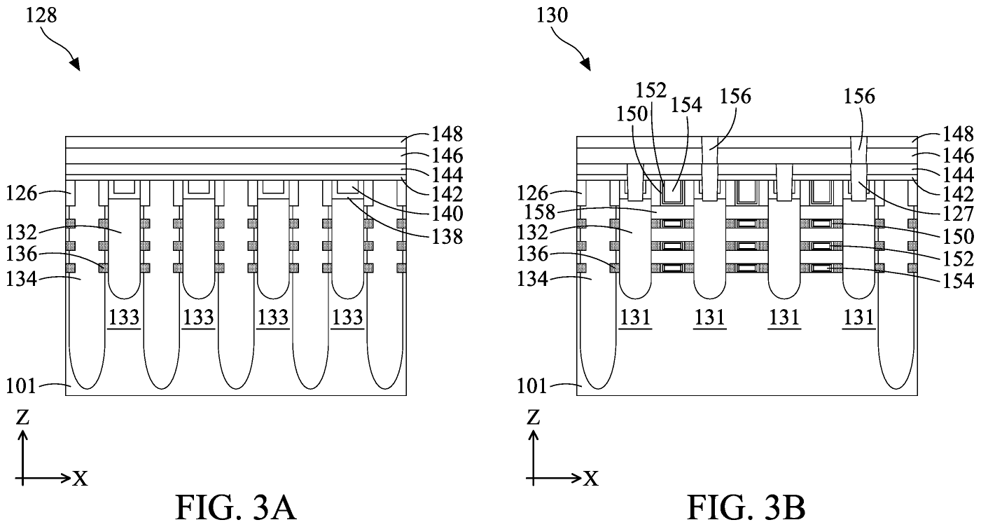

FIG. 3A is an enlarged portion 128 of the semiconductor device structure 100 of FIG. 2, in accordance with some embodiments. The portion 128 may be a portion of the buffer region 116. As shown in FIG. 3A, the portion 128 of the buffer region 116 includes a plurality of S/D regions 132 formed over well regions 133. In some embodiments, the S/D regions 132 include epitaxial features that may be n-type epitaxial features for n-type FETs (NFETs) or p-type epitaxial features for p-type FETs (PFETs). The S/D regions 132 including n-type epitaxial features may include one or more layers of Si, SiP, SiC and SiCP, and the S/D regions 132 including p-type epitaxial features may include one or more layers of Si, SiGe, and Ge. For PFETs, p-type dopants, such as boron (B), may also be included in the S/D regions 132. In some embodiments, the S/D regions 132 includes a dopant of a first type, such as a p-type or an n-type, and the well region 133 includes a dopant of a second type opposite the first type. In other words, a p-type S/D region 132 may be formed on an n-type well region 133, while an n-type S/D region 132 may be formed on a p-type well region 133. In this disclosure, a source region and a drain region are interchangeably used, and the structures thereof are substantially the same. Furthermore, source/drain region(s) may refer to a source or a drain, individually or collectively dependent upon the context.

In some embodiments, the buffer region 116 does not include active devices, and the gate structures and the channel regions are removed and replaced with a dielectric material 134. In some embodiments, the devices formed on the substrate 101 are nanostructure devices, and the channel region includes a plurality of nanostructures. The dielectric material 134 may include any suitable dielectric material 134, such as SiN. In some embodiments, the structure in the buffer region 116 may be formed simultaneously with the active devices in the active region 108, and the gate structures and the channel regions located in the buffer region 116 are replaced with the dielectric material 134 by a continuous poly on diffusion edge (CPODE) process. In some embodiments, the CPODE process does not remove the gate spacers 126 and inner spacers 136. With the dielectric materials 134 replacing the gate structures, the region where the opening for the TSV 102 would be formed is a metal-free space.

As shown in FIG. 3A, a contact etch stop layer (CESL) 138 is formed on the plurality of S/D regions 132, and a first interlayer dielectric (ILD) layer 140 is formed on the CESL 138. The CESL 138 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 138 is a single layer, as shown in FIG. 3A. In some embodiments, the CESL 138 includes two or more layers. The materials for the ILD layer 140 may include compounds including Si, O, C, and/or H, such as silicon oxide, SiCOH, or SiOC. Organic materials, such as polymers, may also be used for the ILD layer 140. The ILD layer 140 may be deposited by a PECVD process or other suitable deposition technique. Another etch stop layer 142 is formed on the gate spacers 126, the dielectric material 134, the CESL 138, and the ILD layer 140. The etch stop layer 142 may include the same material as the CESL 138 and formed by the same process as the CESL 138. Another ILD layer 144 is formed on the etch stop layer 142, another etch stop layer 146 is formed on the ILD layer 144, and another ILD layer 148 is formed on the etch stop layer 146. The ILD layers 144, 148 and the etch stop layers 142, 146 are used to form conductive contacts 127 (FIG. 3B) and conductive vias 156 (FIG. 3B) over the active devices in the active region 108. Because the structure in the buffer region 116 does not include active devices, the conductive contacts 127 and the conductive vias 156 are not formed in the ILD and etch stop layers. The etch stop layer 142, the ILD layer 144, and the conductive contacts 127 may be formed by MOL processes in the region 124 (FIG. 2).

FIG. 3B is an enlarged portion 130 of the semiconductor device structure 100 of FIG. 2, in accordance with some embodiments. The portion 130 may be a portion of the boundary region 106, which is a portion of the active region 108. In some embodiments, the tap cells or boundary cells in the boundary region 106 include nanostructure transistors having the plurality of S/D regions 132 disposed over well regions 131. Tap cells may be implemented to prevent shorting of drain to ground by way of the parasitic bipolar transistors. In some instances, tap cells may be used to couple certain n-type well region (n-well) to Vdd (drain supply voltage or positive supply voltage) and the p-type well region (p-well) on the substrate to Vss (source supply voltage or negative supply voltage). In some implementations, Vdd is the most positive voltage of the STD or IC device and Vss is the most negative voltage of the STD or IC device. Vss may be the ground voltage or may be grounded. Tap cells may take shape of a transistor but they do not have functional gate structures. Tap cells perform their latch-up prevention function through their source/drain regions. Different from transistors in STD, the active regions in a tap cell do not have a different conductivity type from that of the underlying well. For example, when a tap cell is formed over an n-well, it has an active region doped with n-type dopants, rather than p-type dopants. When a tap cell is formed over a p-well, it has an active region doped with p-type dopants, rather than n-type dopants.

In some embodiments, the well regions 131 differ from the well region 133 in that the dopant type of the well regions 131 is the same as the dopant type of the S/D regions 132. For example, the S/D regions 132 may be n-type regions, and the well regions 131 are n-wells. The S/D regions 132 may be p-type regions, and the well regions 131 are p-wells. In some embodiments, for p-type devices, the well regions 131 include SiGe doped with boron. For n-type devices, the well regions 131 include SiP doped with phosphorous. The well regions 131 include dopants of the same type as the dopants of the S/D regions 132 formed thereon in order to perform the function of the tap cells or boundary cells.

As shown in FIG. 3B, the nanostructure transistors further include gate structures. In some embodiments, each gate structure includes a gate dielectric layer 150, one or more work function layers 152, and a gate electrode layer 154. The channel regions may include a plurality of semiconductor layers 158, and the gate structure surround portions of each semiconductor layer 158. The gate structure is disposed between the inner spacers 136, as shown in FIG. 3B. The semiconductor layers 158 may include any suitable semiconductor material, such as undoped silicon. In some embodiments, an interfacial layer (IL) (not shown) is formed between the gate dielectric layer 150 and the semiconductor layers 158. In some embodiments, the gate dielectric layer 150 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 150 may be formed by CVD, ALD or any suitable deposition technique. The work function layer 152 may include polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, or other suitable materials. The gate electrode layer 154 may include one or more layers of conductive material, such as platinum (Pt), palladium (Pd), tantalum (Ta), ytterbium (Yb), aluminum (Al), silver (Ag), titanium (Ti), ruthenium (Ru), molybdenum (Mo), chromium (Cr), tungsten (W), copper (Cu), or similar material, and/or any combinations thereof. The gate electrode layer 154 may be formed by CVD, ALD, electro-plating, or other suitable deposition technique.

Because the tap cells or boundary cells are active, the conductive contacts 127 and the conductive vias 156 are formed in the boundary region 106. In some embodiments, the conductive vias 156 include the same material as the conductive feature 112. In some embodiments, the conductive vias 156 are also conductive features 112 and are part of the interconnect structure 103 (FIG. 2). In some embodiments, the devices of the tap cells or boundary cells are electrically connected to the STD in the active region 108 via the conductive contacts 127, the conductive vias 156, and the conductive features 112. For example, a conductive feature 112 electrically connected to the S/D region 132 in the boundary region 106 may be electrically connected to or in direct contact with a conductive feature 112 electrically connected to the active devices of the STD in the active region 108. In some embodiments, the dummy devices, such as the dummy devices in the dummy region 107 (FIG. 1A-2) located between the guard ring 104 and the TSV 102 are not electrically connected to any active devices, signal sources, or power sources. For example, the semiconductor device structure 100 shown in FIG. 1A-2 may not include the conductive contacts 127, the conductive vias 156, and/or one or more conductive features 112 that are electrically connected to the dummy devices. In some embodiments, the dummy region 107 (FIG. 1A-2) includes a plurality of dummy conductive features disposed in the interconnect structure 103 (FIG. 1B). The dummy conductive features include conductive lines and conductive vias that are not electrically connected to any active devices, signal sources, or power sources. The dummy conductive features may be formed with the conductive features 112 (FIG. 1B). In some embodiments, the dummy conductive features are located between the conductive features 112 (FIG. 1B) disposed in the boundary region 106 (FIG. 1B) and the guard ring 104 (FIG. 1B)

In some embodiments, the active devices in the active region 108 are formed simultaneously with the devices formed in the boundary region 106. For example, the active devices in the active region 108 may include the S/D regions 132 formed on the well regions 133, the semiconductor layers 158 located between the S/D regions 132, and gate structures surrounding a portion of each semiconductor layer 158. The gate structure may include the gate dielectric layer 150, the one or more work function layers 152, and the gate electrode layer 154.

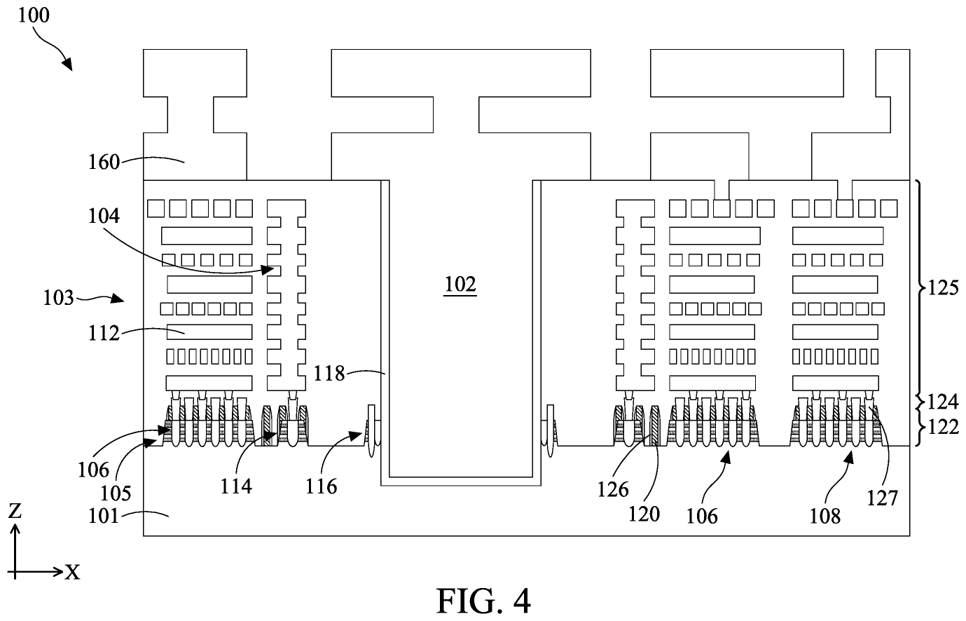

FIG. 4 is a cross-sectional side view of one of various stages of manufacturing the semiconductor device structure 100, in accordance with some embodiments. As shown in FIG. 4, the liner 118 and the TSV 102 are formed in the interconnect structure 103, the buffer region 116, and the substrate 101. In some embodiments, an opening is first formed in the interconnect structure 103, the buffer region 116, and the substrate 101, the liner 118 is then formed in the opening, followed by forming the TSV 102 on the liner 118 in the opening. As described above, there are no materials made of metal in the portion of the interconnect structure 103 and the buffer region 116 in which the opening is formed. Thus, the formation of the opening may be easier without the metal materials. Additional conductive features 160, such as redistribution layers (RDLs), bonding pads and/or bonding structures, are formed over the interconnect structure 103. In some embodiments, the conductive vias 156 are electrically connected to the active devices of the STD in the active region 108 by the RDLs.

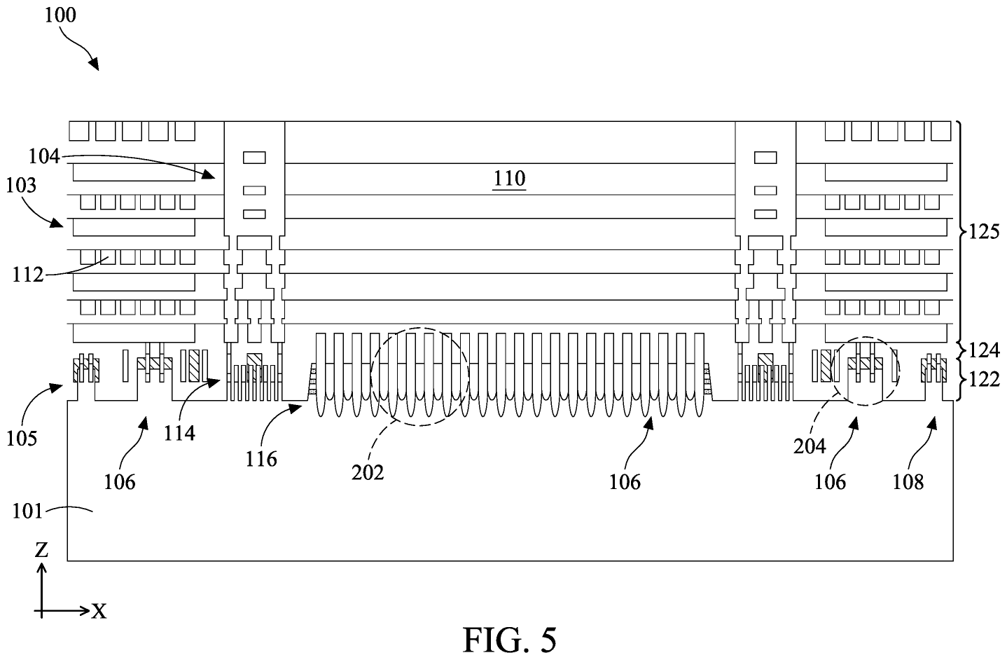

FIG. 5 is a cross-sectional side view of one of various stages of manufacturing the semiconductor device structure 100, in accordance with alternative embodiments. The embodiments shown in FIGS. 2 to 4 includes active devices that are nanostructure transistors. In some embodiments, the active devices are FinFETs. As shown in FIG. 5, the plurality of devices 105 are FinFETs, and the dummy devices 114 and the buffer region 116 are based on FinFET structures. In some embodiments, the devices of the tap cells or boundary cells in the boundary region 106 is adjacent the dummy devices 114 of the guard ring 104, and the space between the devices in the boundary region 106 and the dummy devices 114 is free of dummy devices and/or the space between the conductive features 112 in the boundary region 106 and the guard ring 104 is free of dummy conductive features. In some embodiments, only a dielectric material, such as the dielectric layer 110, the CESL 138, the ILD layer 140, or other suitable dielectric material is disposed between the devices in the boundary region 106 and the dummy devices 114. In some embodiments, only the dielectric layer 110 is disposed between the conductive features 112 and the guard ring 104.

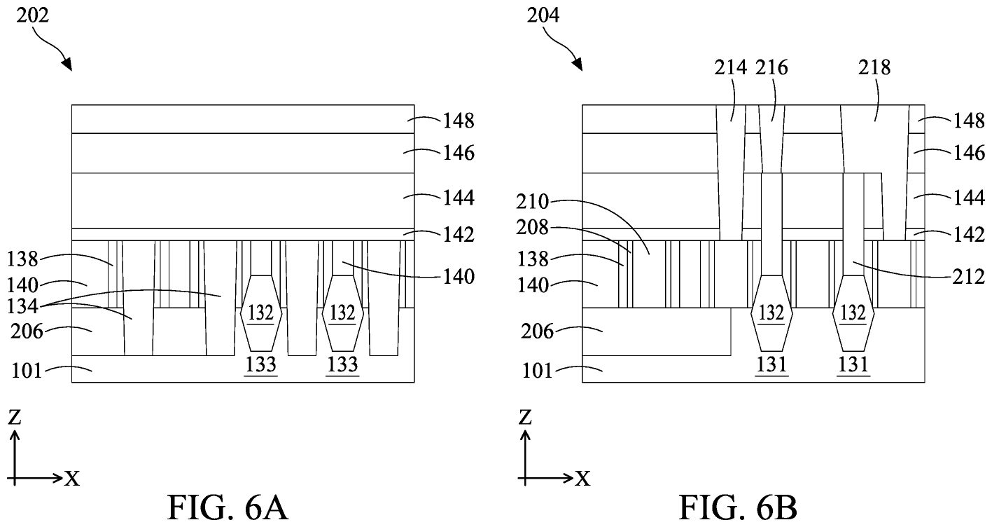

FIG. 6A is an enlarged portion 202 of the semiconductor device structure 100 of FIG. 5, in accordance with some embodiments. The portion 202 may be a portion of the buffer region 116. As shown in FIG. 6A, the portion 202 of the buffer region 116 includes the plurality of S/D regions 132 formed over well regions 133, and the dielectric material 134 formed to replace the gate structures and channel regions. The portion 202 of the buffer region 116 further includes an isolation region 206, such as the shallow trench isolation (STI). The CESL 138, the ILD layers 140, 144, 148, and the etch stop layers 142, 146 may be formed in similar manners as described in FIG. 3A.

FIG. 6B is an enlarged portion 204 of the semiconductor device structure 100 of FIG. 5, in accordance with some embodiments. The portion 204 may be a portion of the boundary region 106, which is a portion of the active region 108. In some embodiments, the tap cells or boundary cells in the boundary region 106 include FinFETs having the plurality of the S/D regions 132 disposed over the well regions 131. The well regions 131 has the same dopant type as that of the S/D regions 132. For example, the S/D regions 132 may be n-type regions, and the well regions 131 are n-wells. The S/D regions 132 may be p-type regions, and the well regions 131 are p-wells. In some embodiments, for p-type devices, the well regions 131 include SiGe doped with boron. For n-type devices, the well regions 131 include SiP doped with phosphorous. Gate structures 210 may be formed over the substrate, while gate spacers 208 are formed on sidewalls of the gate structures 210. In some embodiments, the gate structure 210 includes a gate dielectric layer, one or more work function layers, and a gate electrode layer. The gate dielectric layer may include the same material as the gate dielectric layer 150 (FIG. 3B), the one or more work function layers may include the same material as the work function layers 152 (FIG. 3B), and the gate electrode layer may include the same material as the gate electrode layer 154 (FIG. 3B). Conductive contacts 212 are formed in the ILD layers 140, 144 and the etch stop layer 142. Conductive vias 216 are formed in the ILD layer 148 and the etch stop layer 146. The conductive contacts 212 may include the same material as the conductive contacts 127 (FIG. 3B), and the conductive vias 216 may include the same material as the conductive vias 156 (FIG. 3B). In some embodiments, the structure in the boundary region 106 further includes conductive features 214, 218 electrically connected to the gate structures 210. The conductive features 214, 218 may include the same material as the conductive features 112. In some embodiments, the conductive feature 218 is electrically connected to both the gate structure 210 and the S/D region 132.

Because the tap cells or boundary cells are active, the conductive contacts 212 and the conductive vias 216 are formed in the boundary region 106. In some embodiments, the conductive vias 216 are also conductive features 112 and are part of the interconnect structure 103 (FIG. 2). In some embodiments, the devices of the tap cells or boundary cells are electrically connected to the STD in the active region 108 via the conductive contacts 212, the conductive vias 216, and the conductive features 112. For example, a conductive feature 112 electrically connected to the S/D region 132 in the boundary region 106 may be electrically connected or in direct contact with a conductive feature 112 electrically connected to the active devices of the STD in the active region 108. The dummy devices located between a guard ring and a TSV of a conventional structure are not electrically connected to any active devices, signal sources, or power sources. For example, a conventional structure may not include the conductive contacts 212, the conductive vias 216, and/or one or more conductive features 112 that are electrically connected to the dummy devices.

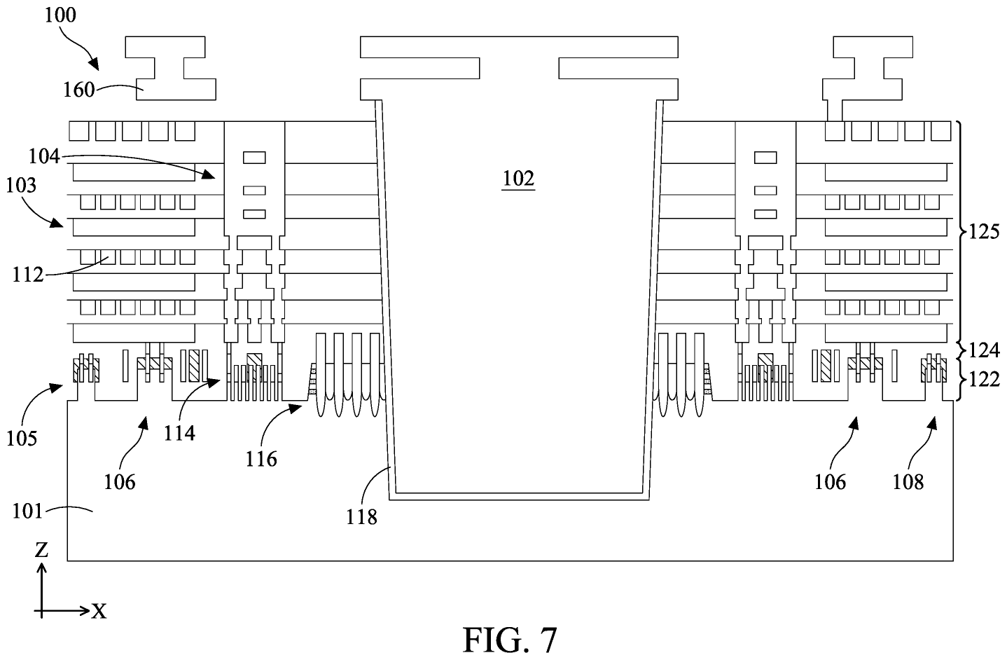

FIG. 7 is a cross-sectional side view of one of various stages of manufacturing the semiconductor device structure 100, in accordance with some embodiments. As shown in FIG. 7, the liner 118 and the TSV 102 are formed in the interconnect structure 103, the buffer region 116, and the substrate 101. In some embodiments, an opening is first formed in the interconnect structure 103, the buffer region 116, and the substrate 101, the liner 118 is then formed in the opening, followed by forming the TSV 102 on the liner 118 in the opening. As described above, there are no materials made of metal in the portion of the interconnect structure 103 and the buffer region 116 in which the opening is formed. Thus, the formation of the opening may be easier without the metal materials. The conductive features 160 are formed over the interconnect structure 103.

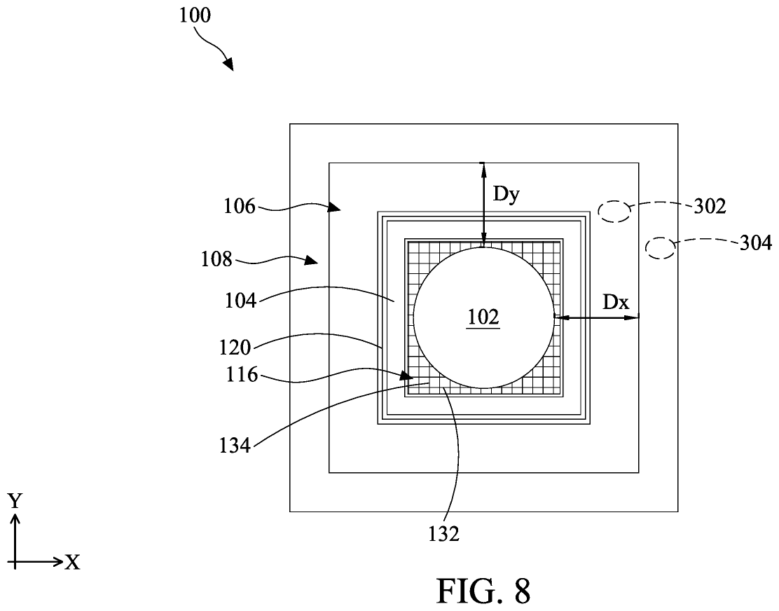

FIG. 8 is a top view of the semiconductor device structure 100, in accordance with some embodiments. As shown in FIG. 8, the buffer region 116 includes the S/D regions 132 and the dielectric material 134, and the buffer region 116 is surrounded by the guard ring 104. In some embodiments, the conductive feature 120 surrounds the guard ring 104, and the boundary region 106 surrounds the conductive feature 120. The KOZ is defined by the dimensions Dx and Dy. In some embodiments, when designing a circuit including the semiconductor device structure 100, an electronic device automation (EDA) tools may first check the design rule and then define the KOZ based on the location of the TSV 102 and the dimensions Dx and Dy. Next, tap cells or boundary cells, such as the structures shown in FIGS. 3B and 6B are placed in the KOZ. Thus, the conventional process to place dummy devices in the KOZ, particularly between the guard ring 104 and the active devices, may be omitted. As a result, the dimensions of the KOZ become smaller, and active device density may be increased.

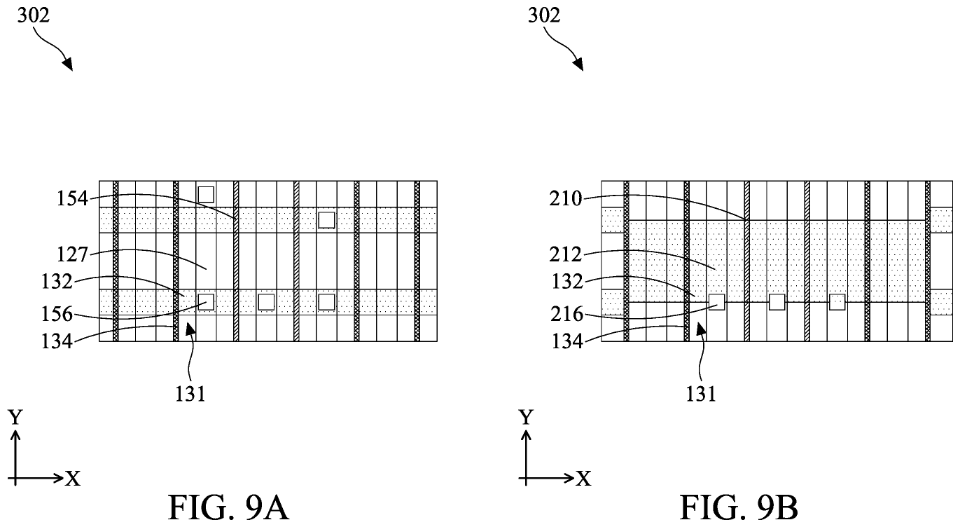

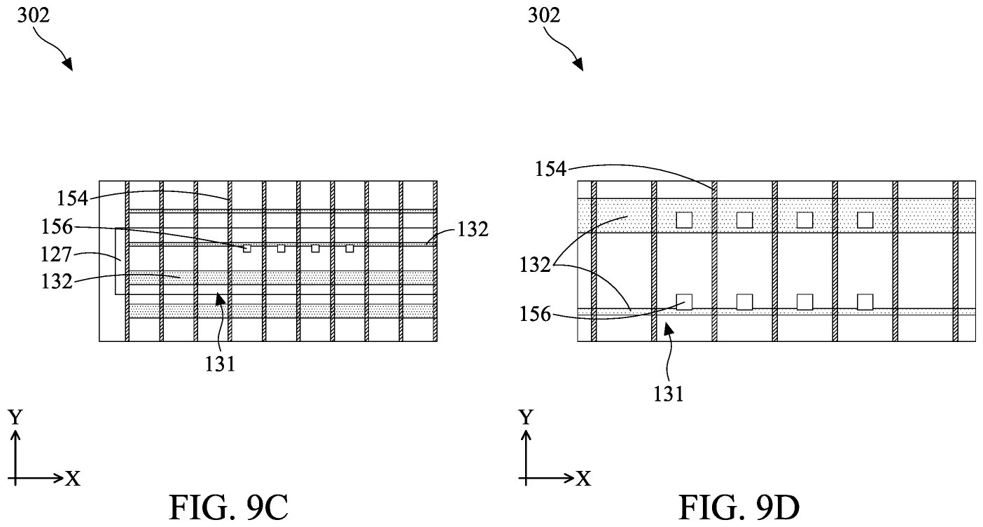

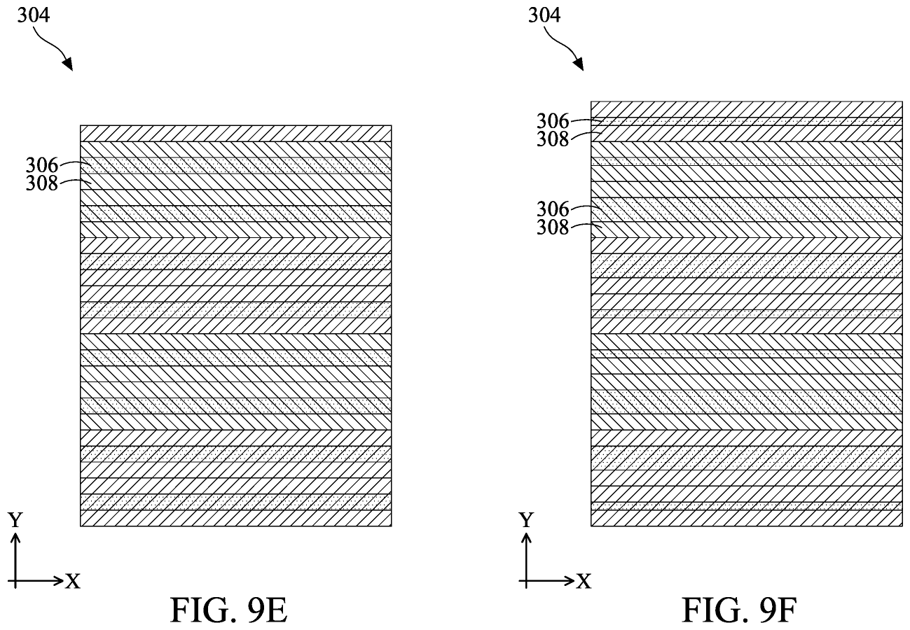

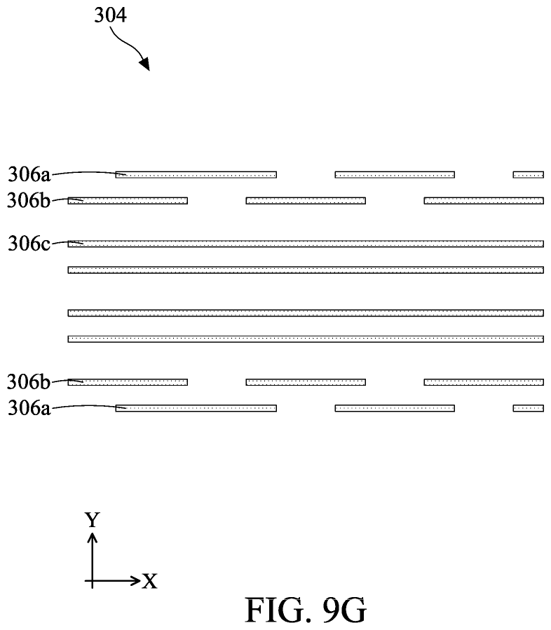

FIGS. 9A-9D illustrate an enlarged portion 302 of the semiconductor device structure 100 of FIG. 8, and FIGS. 9E-9G illustrate an enlarged portion 304 of the semiconductor device structure 100 of FIG. 8, in accordance with some embodiments. The portion 302 in the boundary region 106 includes tap cells or boundary cells, such as STD boundary tap, logic pick-up, or SRAM tap. As shown in FIG. 9A, the tap cells or boundary cells include nanostructure transistors having the S/D regions 132, the dielectric material 134, the gate electrode layers 154, the conductive contacts 127, and the conductive vias 156. As described above, the well region 131 includes the same dopant type as the S/D regions 132. Thus, in some embodiments, the S/D region 132 includes an n-type epitaxial material, such as SiP, and the well region 131 is an n-well doped with phosphorous. In some embodiments, the S/D region 132 includes a p-type epitaxial material, such as SiGe, and the well region 131 is a p-well doped with boron.

As shown in FIG. 9B, the tap cells or boundary cells include FinFETs having the S/D regions 132, the dielectric material 134, the gate structures 210, the conductive contacts 212, and the conductive vias 216. As described above, the well region 131 includes the same dopant type as the S/D regions 132. Thus, in some embodiments, the S/D region 132 includes an n-type epitaxial material, such as SiP, and the well region 131 is an n-well doped with phosphorous. In some embodiments, the S/D region 132 includes a p-type epitaxial material, such as SiGe, and the well region 131 is a p-well doped with boron.

As shown in FIG. 9C, the tap cells or boundary cells include FinFETs or nanostructure transistors having the S/D regions 132, the gate electrode layers 154, the conductive contact 127, and the conductive vias 156. In some embodiments, the widths of the fins of the FinFETs or nanostructure transistors may be different. For example, as shown in FIG. 9C, the widths along the Y direction of the S/D regions 132 are different. Similarly, the widths of the channels (portions of the fins under the gate electrode layers 154) are also different. As described above, the well region 131 includes the same dopant type as the S/D regions 132. Thus, in some embodiments, the S/D region 132 includes an n-type epitaxial material, such as SiP, and the well region 131 is an n-well doped with phosphorous. In some embodiments, the S/D region 132 includes a p-type epitaxial material, such as SiGe, and the well region 131 is a p-well doped with boron.

As shown in FIG. 9D, the tap cells or boundary cells include FinFETs or nanostructure transistors having the S/D regions 132, the gate electrode layers 154, and the conductive vias 156. Similar to FIG. 9C, the widths of the fins of the FinFETs or nanostructure transistors may be different. For example, as shown in FIG. 9D, the widths of the S/D regions 132 are different, and the widths of the channels are also different. As described above, the well region 131 includes the same dopant type as the S/D regions 132. Thus, in some embodiments, the S/D region 132 includes an n-type epitaxial material, such as SiP, and the well region 131 is an n-well doped with phosphorous. In some embodiments, the S/D region 132 includes a p-type epitaxial material, such as SiGe, and the well region 131 is a p-well doped with boron.

FIGS. 9E-9G illustrate an enlarged portion 304 of the semiconductor device structure 100 of FIG. 8, in accordance with some embodiments. The portion 304 in the active region 108 includes active cells, such as STD cells, logic cells, or SRAM cells. In some embodiments, the portion 304 includes STD cells having a plurality of active fin patterns 306. Each active fin pattern 306 may include a plurality of S/D regions, such as the S/D regions 132, formed from well regions 308, such as the well regions 133. As described above, in the active region 108, the active cells includes S/D regions and well portions having opposite types of impurity. For example, the well region 308 is a p-type region, and the S/D region of the fin pattern 306 formed thereon includes an n-type epitaxial material. The fin pattern 306 may also include channels surrounded by gate electrode layers (not shown), such as the gate electrode layers 154. In some embodiments, the fin patterns 306 have the same width along the Y direction, as shown in FIG. 9E. In some embodiments, the fin patterns 306 have different widths along the Y direction, as shown in FIG. 9F.

In some embodiments, as shown in FIG. 9G, the portion 304 includes SRAM cells having staggered fin patterns 306. For example, the portion 304 includes discrete fin pattern 306a and discrete fin pattern 306b, as shown in FIG. 9G. Each fin pattern 306a, 306b includes groups of one or more transistors. For example, each group includes at least a source region, a drain region, and a channel region. The channel region is surrounded by a gate electrode layer (not shown). In some embodiments, the groups of transistors of the fin patterns 306a, 306b are staggered along the Y direction, as shown in FIG. 9G. In some embodiments, multiple fin patterns 306a, 306b are separated by fin patterns 306c, and each fin pattern 306c is a continuous fin pattern.

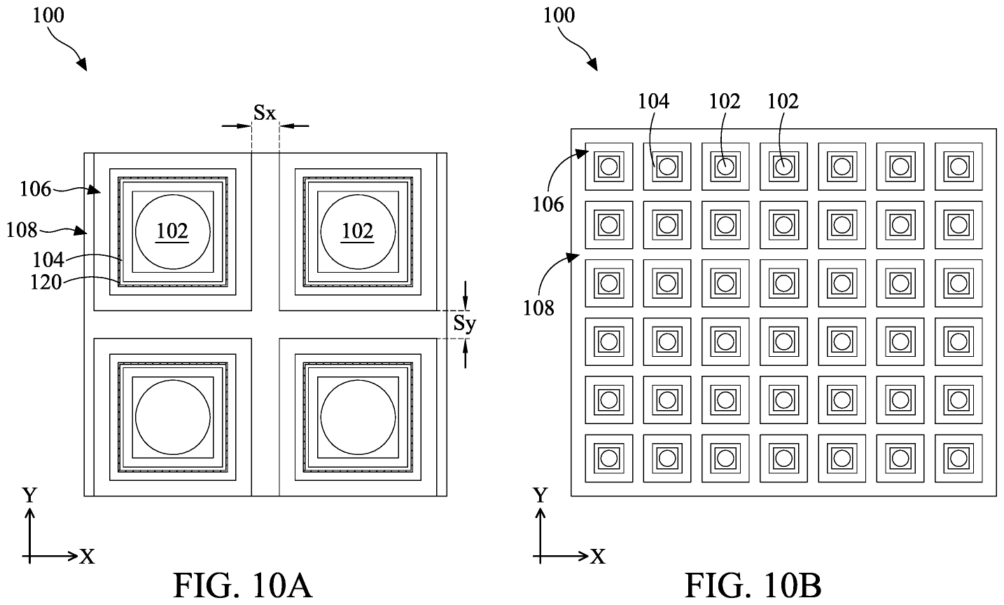

FIGS. 10A and 10B are top views of the semiconductor device structure 100, in accordance with some embodiments. As shown in FIGS. 10A and 10B, the semiconductor device structure 100 includes multiple TSVs 102 arranged adjacent to each other. An example of such arrangement may be in SoIC F2B stacking (2-dice). Eliminating dummy devices in the KOZ (between the guard ring 104 and the active devices of the active region 108) leads to reduced dimensions Dx, Dy, of the KOZ, as shown in FIG. 1A-1. In alternative embodiments, the TSV KOZ includes the boundary region 106, which includes the outermost boundary cells or tap cells of STD, as shown in FIG. 1A. As a result, the active STD in circuit can exist in the space between adjacent TSVs 102. Due to short routing, the circuit including adjacent TSVs 102 as shown in FIGS. 10A and 10B has high signal transmission efficiency. In some embodiments, the active region 108 between horizontally adjacent TSVs 102 has a dimension Sx, and the active region 108 between vertically adjacent TSVs 102 has a dimension Sy. In some embodiments, the ratio of Sx to Sy is greater than or equal to about 1. In some embodiments, the TSV 102 has a pitch of less than or equal to 10 microns. Conventional TSVs with a pitch of less than or equal to 10 microns includes dummy devices in the KOZ, leading to reduced space for active devices between adjacent TSVs.

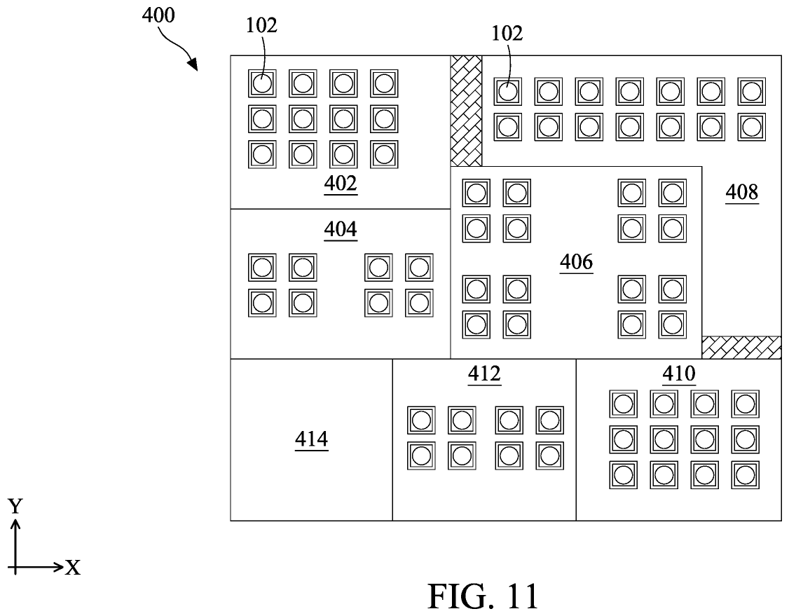

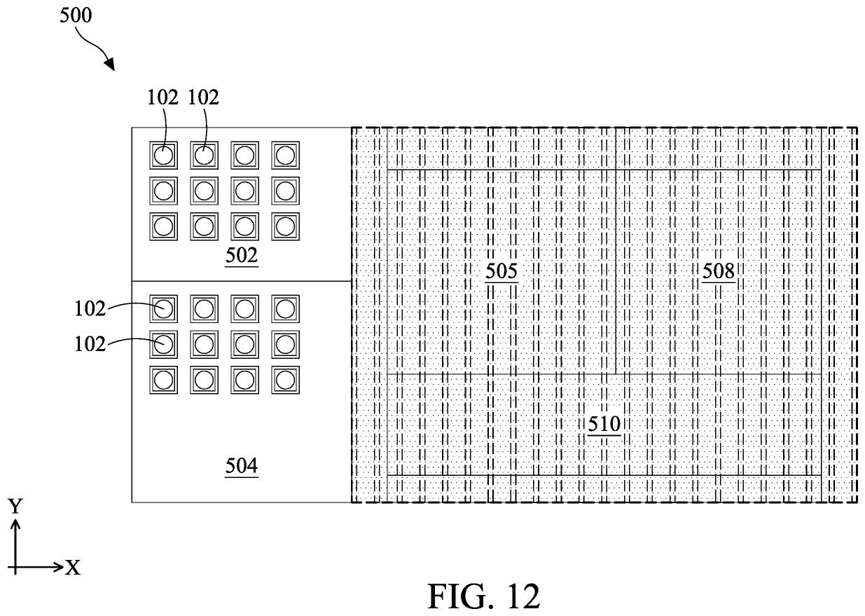

FIGS. 11 and 12 illustrates IC design layouts including the semiconductor device structure 100, in accordance with some embodiments. An IC design layout typically includes various intellectual property (IP) blocks, where each IC pattern is classified based on an IP block to which the IC pattern belongs. An IP block generally refers to a reusable, custom designed logic component, storage component, or other component. For example, as shown in FIG. 11, an IC design layout 400 includes IP blocks 402, 404, 406, 408, 410, 412, 414. The IP blocks 402, 404, 406, 408, 410, 412, 414 may be any suitable IP blocks. In some embodiments, the IP block 402 includes a first STD, the IP block 408 includes a second STD, the IP block 410 includes a third STD, the IP block 404 includes a first SRAM cell, the IP block 406 includes a second SRAM cell, the IP block 412 includes a third SRAM cell, and the IP block 414 includes other IP. At least one of the IP blocks 402, 404, 406, 408, 410, 412, 414 includes one or more TSVs 102. As shown in FIG. 11, the TSVs 102 are formed inside of the IP blocks 402, 404, 406, 408, 410, 412, 414, as a result of increased space for active devices between adjacent TSVs 102. As a result of such arrangements of the IP blocks, die-to-die signal transmission increased due to short routing, which may benefit high speed computing with lower power consumption for applications such as GPU or AI.

As shown in FIG. 12, an IC design layout 500 for near-memory compute (NMC) applications in 3DIC includes IP blocks 502, 504, 506, 508, 510. In some embodiments, the IP block 502 includes a first STD (CPU/GPU), the IP block 504 includes a logic cell, the IP block 506 includes a SRAM cell, the IP block 508 includes a second STD (SRAM periphery), and the IP block 510 includes a third STD (SRAM periphery). As described above, active devices, such as active STD cells in the IP block 502 and active logic cells in the IP block 504, may be formed between adjacent TSVs 102. With the TSVs 102 located inside of the IP blocks 502, 504, the efficiency of data movement between the IP block 502 and IP block 506 is enhanced.

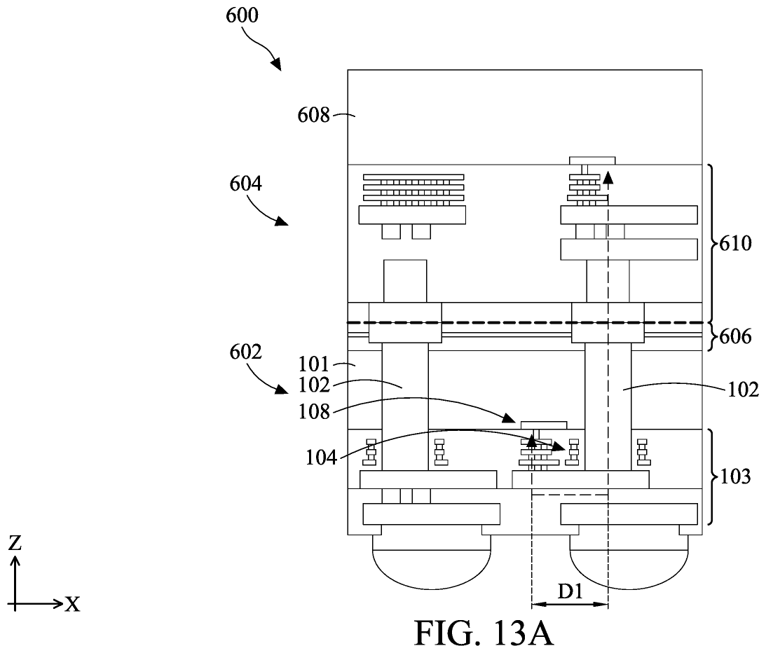

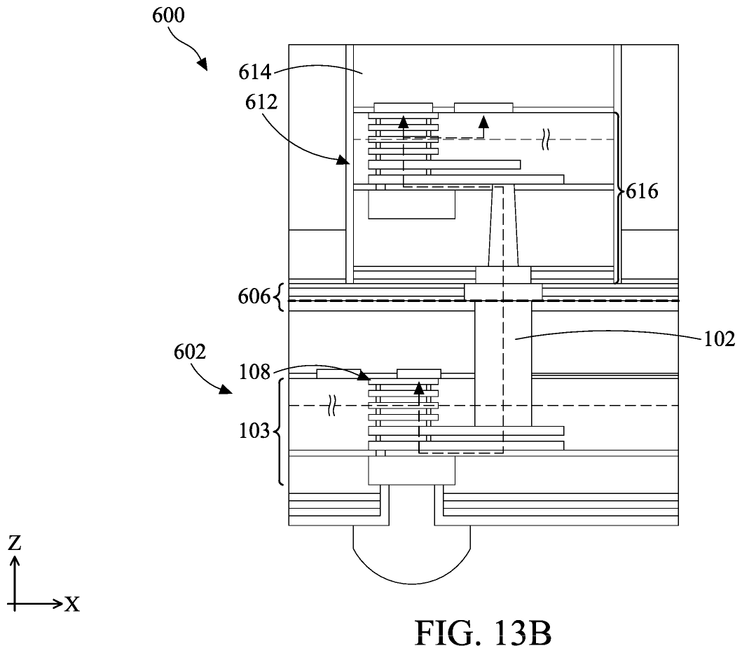

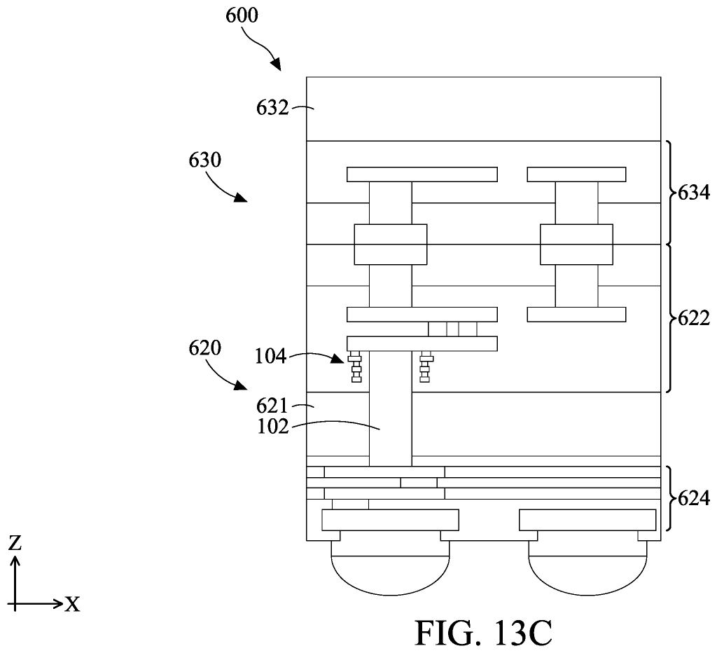

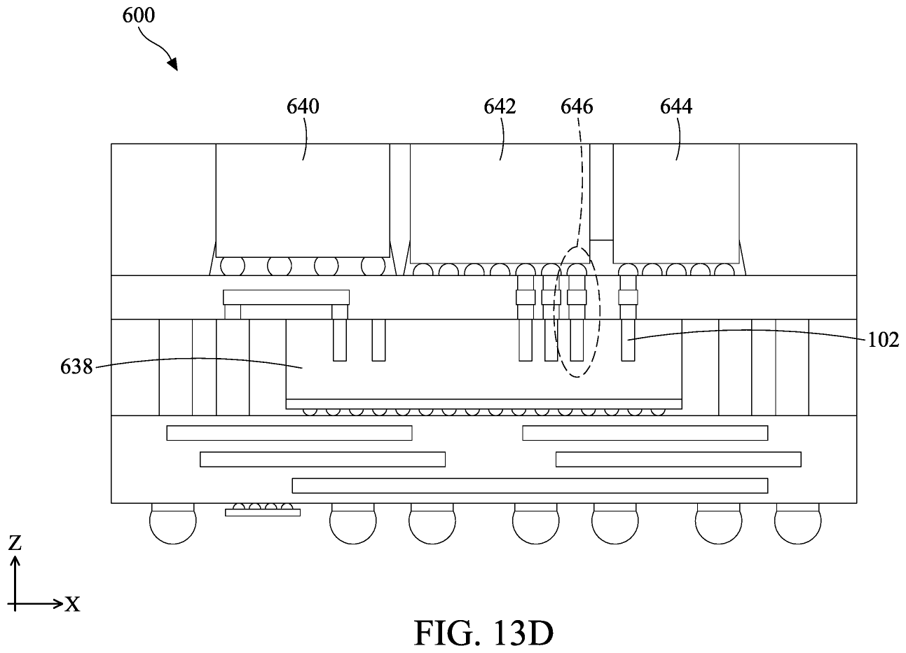

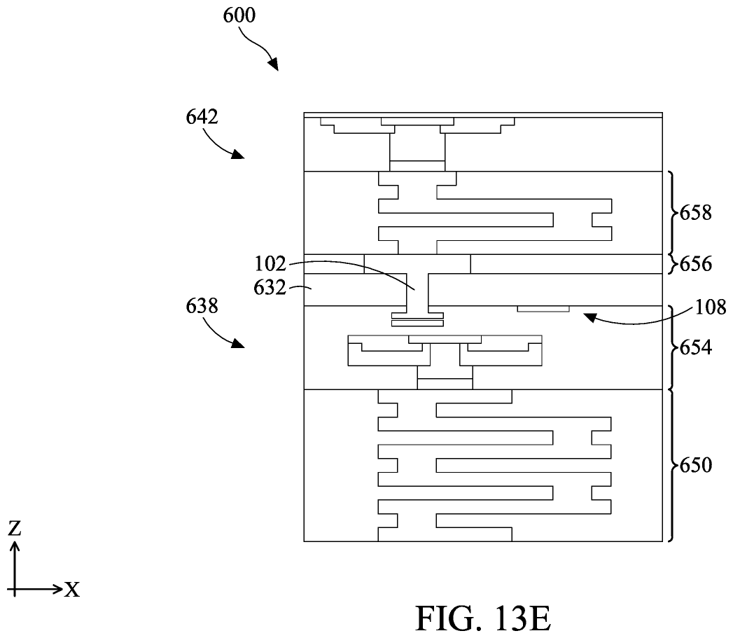

FIGS. 13A-13E illustrate semiconductor packages 600, in accordance with some embodiments. Components, such as the boundary region 106 and the buffer region 116 may be omitted in FIGS. 13A-13E for clarity. As shown in FIG. 13A, the semiconductor package 600 may be a SoIC/InFO F2B package having a first die 602 and a second die 604 disposed on the first die 602. The second die 604 includes a substrate 608 and an interconnect structure 610. Actives devices are formed on a front side of the substrate 608, and the interconnect structure 610 is formed on the front side of the substrate 608. The first die 602 includes the substrate 101, the interconnect structure 103, and a back side interconnect structure 606. The interconnect structure 610 of the second die 604 is bonded to the back side interconnect structure 606 of the first die 602. As shown in FIG. 13A, active devices in the active region 108 of the first die 602 are formed on a front side of the substrate 101. In some embodiments, active devices in the active region 108 are located between two TSVs 102, and the TSVs 102 has a pitch less than about 10 microns. In some embodiments, the tap or boundary cells located in the boundary region (not shown) are disposed between the active devices in the active region 108 and the guard ring 104. By placing active devices in the active region 108 located between adjacent TSVs 102, the distance D1 between the TSV 102 and the active device in the active region 108 is reduced. As a result, signal bandwidth in CPU/GPU and SRAM periphery is widened, and power consumption is lowered. As shown in FIG. 13A, the space between the guard ring 104 and the active devices in the active region 108 is free of dummy devices.

As shown in FIG. 13B, the semiconductor package 600 may be used in near-memory compute (NMC) application and includes the first die 602 and a second die 612 disposed on the first die 602. The second die 612 includes a substrate 614 and an interconnect structure 616. Actives devices are formed on a front side of the substrate 614, and the interconnect structure 616 is formed on the from side of the substrate 614. The interconnect structure 616 of the second die 612 is bonded to the backside interconnect structure 606 of the first die 602. Guard ring 104 is omitted in FIG. 13B for clarity. As shown in FIG. 13B, active devices in the active region 108 of the first die 602 are formed on the front side of the substrate 101. As shown in FIG. 13B, the TSV 102 provide an electrical path between the active devices, such as CPU/GPU or SRAM macro, in the second die 612 and the active devices, such as CPU/GPU, in the first die 602. In some embodiments, the distance between the TSV 102 and the active device is reduced, due to the dummy device free KOZ. As a result, signal bandwidth in CPU/GPU and SRAM micro is widened, and power efficiency is improved.

As shown in FIG. 13C, the semiconductor package 600 may be a SoIC F2F package having a first die 620 and a second die 630 disposed on the first die 620. The second die 630 includes a substrate 632 and an interconnect structure 634. Actives devices (not shown) are formed on a front side of the substrate 632, and the interconnect structure 634 is formed on the front side of the substrate 632. The first die 620 includes a substrate 621, a front side interconnect structure 622, and a back side interconnect structure 624. The interconnect structure 634 of the second die 630 is bonded to the front side interconnect structure 622 of the first die 620. Active devices (not shown) of the first die 620 are formed on a front side of the substrate 621. In some embodiments, the distance between the TSV 102 and the active device is reduced, due to the dummy device free KOZ. As a result, signal bandwidth is widened, and power consumption is lowered.

As shown in FIG. 13D, the semiconductor package 600 may be an INFO-3D F2B package including a first die 640, a second die 642, a third die 644, and a fourth die 638 disposed below the first, second, and third dies 640, 642, 644. A plurality of TSVs 102 are formed in the fourth die 638 to electrically connect to the first, second, and third dies 640, 642, 644. FIG. 13E is an enlarged view of a portion 646 of the semiconductor package 600 of FIG. 13D. As shown in FIG. 13E, the fourth die 638 is disposed over a redistribution layer 650 (or an interposer). A plurality of conductive features are disposed in the redistribution layer 650. Another redistribution layer 658 is disposed over the fourth die 638, and the second die 642 is disposed over the redistribution layer 658. As shown in FIG. 13E, the fourth die 638 includes a substrate 632, a front side interconnect structure 654, and a back side interconnect structure 656. The TSV 102 is formed through the substrate 632. Active devices of the active region 108 are formed on the front side of the substrate 632. In some embodiments, the distance between the TSV 102 and the active device is reduced, due to the dummy device free KOZ. As a result, signal bandwidth is widened, and power consumption is lowered.

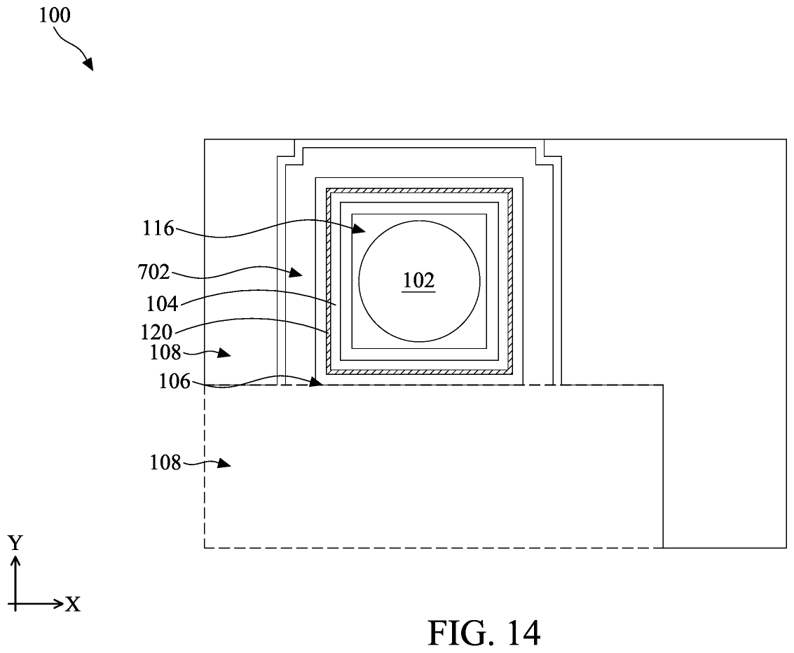

FIG. 14 is a top view of the semiconductor device structure 100, in accordance with alternative embodiments. In some embodiments, the guard ring 104 is not surrounded by the boundary region 106. For example, the boundary region 106 may be adjacent one, two, or three sides of the guard ring 104. In some embodiments, the boundary region 106 is below the TSV 102. As shown in FIG. 14, a dummy device region 702 is located adjacent three sides (left, right and top) of the guard ring 104, and the dummy device region 702 includes a plurality of dummy devices. As described above, a dummy device may be a transistor including a gate electrode, a source region, a drain region, and a channel region between the source region and the drain region. However, the dummy device is not electrically connected to a signal source, a power source, or any active devices. The boundary cells or tap cells (represented by the dotted line located at outer edge of the active region 108) of the boundary region 106 are located below the guard ring 104. The boundary cells or taps cells may include the structures shown in FIGS. 3B and 6B.

Embodiments of the present disclosure provide a semiconductor device structure 100 including a TSV 102, a KOZ surrounding the TSV 102, and an active region 108 surrounding the KOZ. In some embodiments, a guard ring 104 is located in the KOZ, and the KOZ is free of dummy devices and/or dummy conductive features between the guard ring 104 and the active region 108. Some embodiments may achieve advantages. For example, the KOZ without the dummy devices reduces the size of the KOZ. As a result, high signal bandwidth, high power efficiency, lower area overhead, better latch-up, and better STD PPA may be achieved.

An embodiment is a semiconductor device structure. The structure includes a through silicon via (TSV) disposed in an interconnect structure and a substrate, a guard structure located in the interconnect structure surrounding the TSV, and an active region surrounding the guard structure. A space between the guard structure and the active region is free of dummy devices.

Another embodiment is a semiconductor device structure. The structure includes a substrate, an interconnect structure disposed over the substrate, a guard structure disposed in the interconnect structure, and a first through silicon via (TSV) disposed in the interconnect structure and the substrate. The guard structure surrounds the first TSV. The structure further includes a first boundary region surrounding the guard structure, and the first boundary region includes a first device adjacent the guard structure. A space between the guard structure and the first device is free of dummy device. The boundary region further includes a plurality of conductive features disposed in the interconnect structure over the first device, and the plurality of conductive features surrounds the guard structure.

A further embodiment is a semiconductor package. The semiconductor package includes a first die having a first substrate, a first interconnect structure disposed under the first substrate, a through silicon via (TSV) disposed in the first substrate and the first interconnect structure, and a guard structure surrounding the TSV. The guard structure extends in the first interconnect structure. The first die further includes a first device disposed over the substrate and a first plurality of conductive features disposed in the first interconnect structure over the first device. A space between the first plurality of conductive features and the guard structure is free of dummy conductive features. The first die further includes a second device disposed adjacent the first device. The semiconductor package further includes a second die having a second interconnect structure disposed over the first die and a second substrate disposed over the second interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a through silicon via (TSV) disposed in an interconnect structure and a substrate;
a guard structure located in the interconnect structure surrounding the TSV; and
an active region surrounding the guard structure, wherein a space between the guard structure and the active region is free of dummy devices.

2. The semiconductor device structure of claim 1, further comprising a boundary region located between the guard structure and the active region.

3. The semiconductor device structure of claim 2, wherein the boundary region comprises a first device including a first source/drain region having a dopant of a first type formed on a first well region having a dopant of the first type.

4. The semiconductor device structure of claim 3, wherein the first type is n-type.

5. The semiconductor device structure of claim 3, wherein the first type is p-type.

6. The semiconductor device structure of claim 3, wherein the active region comprises a second device including a second source/drain region having a dopant of a first type formed on a second well region having a dopant of a second type opposite the first type.

7. The semiconductor device structure of claim 3, wherein the first device further comprises a plurality of semiconductor layers connected to the first source/drain region and a gate structure surrounding a portion of each of the semiconductor layers.

8. The semiconductor device structure of claim 3, wherein the first device is a FinFET, CFET, nanostructure transistor, or forksheet FET.

9. The semiconductor device structure of claim 1, wherein the guard structure comprises one or more guard rings.

10. A semiconductor device structure, comprising:
a substrate;
an interconnect structure disposed over the substrate;
a guard structure disposed in the interconnect structure;
a first through silicon via (TSV) disposed in the interconnect structure and the substrate, wherein the guard structure surrounds the first TSV; and
a first boundary region surrounding the guard structure, wherein the first boundary region comprises:
a first device adjacent the guard structure, wherein a space between the guard structure and the first device is free of dummy devices; and
a plurality of conductive features disposed in the interconnect structure over the first device, wherein the plurality of conductive features surrounds the guard structure.

11. The semiconductor device structure of claim 10, wherein the first device is a part of a tap cell.

12. The semiconductor device structure of claim 10, further comprising a second TSV disposed adjacent the first TSV and a second boundary region surrounding the second TSV.

13. The semiconductor device structure of claim 12, further comprising second devices disposed between the first and second boundary regions.

14. The semiconductor device structure of claim 12, wherein the first and second TSVs are located inside of an IP block.

15. The semiconductor device structure of claim 13, wherein the first and second devices are FinFETs, CFETs, nanostructure transistors, or forksheet FETs.

16. The semiconductor device structure of claim 10, further comprising a liner and a barrier, wherein the first TSV is disposed on the barrier, and the barrier comprises Ti or Ta.

17. The semiconductor device structure of claim 13, wherein the first device comprises a first source/drain region having a dopant of a first type formed on a first well region having a dopant of the first type, and the second device comprises a second source/drain region having a dopant of the first type formed on a second well region having a dopant of a second type opposite the first type.

18. A semiconductor package, comprising
a first die, comprising:
a first substrate;
a first interconnect structure disposed under the first substrate;
a through silicon via (TSV) disposed in the first substrate and the first interconnect structure;
a guard structure surrounding the TSV, wherein the guard structure extends in the first interconnect structure;
a first device disposed over the substrate;
a first plurality of conductive features disposed in the first interconnect structure over the first device, wherein a space between the first plurality of conductive features and the guard structure is free of dummy conductive features; and
a second device disposed adjacent the first device; and
a second die, comprising:
a second interconnect structure disposed over the first die; and
a second substrate disposed over the second interconnect structure.

19. The semiconductor package of claim 18, wherein the first device comprises a first source/drain region having a dopant of a first type formed on a first well region having a dopant of the first type, and the second device comprises a second source/drain region having a dopant of the first type formed on a second well region having a dopant of a second type opposite the first type.

20. The semiconductor package of claim 18, further comprising a boundary region surrounding the guard structure, wherein the first device is located in the boundary region, and the boundary region is free of dummy devices.
